(19) United States
(12) Patent Application Publication
(10) Pub. No.: US 2026/0337210 A1
(43) Pub. Date: Oct. 29, 2026

(54) SILICON PRECURSORS FOR DEPOSITION PROCESSES

(71) Applicant: ENTEGRIS, INC., Billerica, MA (US)

(72) Inventors: DaHye Kim, Suwon-si (KR); MinSeok Ryu, Yeonsu-gu (KR); YeRim Yeon, Suwon-si (KR)

(21) Appl. No.: 19/642,584

(22) Filed: Apr. 8, 2026

Related U.S. Application Data
(60) Provisional application No. 63/791,260, filed on Apr. 18, 2025.

(51) Int. Cl. C07F 7/18; C23C 16/42

(52) U.S. Cl. CPC C07F 7/1804; C23C 16/42

(57) ABSTRACT

Precursors for deposition processes are provided. A precursor comprises a silicon-containing precursor. When at least the silicon-containing precursor is exposed to a substrate under deposition conditions, the precursor forms a film having less than 1% by weight of an impurity based on a total weight of the film. Related methods, related systems, related components, related articles, and the like are also provided.

### CROSS-REFERENCE TO RELATED APPLICATIONS

This application claims the benefit under 35 USC 119 of U.S. Provisional Patent Application No. 63/791,260, filed Apr. 18, 2025, the disclosure of which is hereby incorporated herein by reference in its entirety.

### FIELD

The present disclosure relates to silicon precursors for deposition processes, and related compositions and related methods, among other things.

### BACKGROUND

Deposition processes use precursors. The precursors are vaporized and deposited on substrates as films.

### SUMMARY

Some embodiments relate to a composition. In some embodiments, the composition comprises a precursor. In some embodiments, the precursor comprises a compound of the formula:

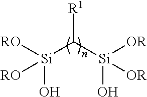

In some embodiments, R is independently a hydrogen or an alkyl, or two of the R attached to the Si are bonded to form a heterocyclic ring. In some embodiments, R¹ is independently at least one of an alkyl, an alkenyl, an alkoxy, an aryl, a cycloalkyl, or any combination thereof. In some embodiments, n is 0 to 3. In some embodiments, when at least the precursor is exposed to a substrate, and optionally a catalyst, under deposition conditions, the precursor forms a film having less than 1% by weight of an impurity based on a total weight of the film.

Some embodiments relate to a method. In some embodiments, the method comprises exposing, under deposition conditions, a substrate to at least a precursor of the formula:

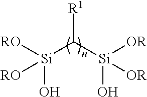

In some embodiments, R is independently a hydrogen or an alkyl, or two of the R attached to the Si are bonded to form a heterocyclic ring. In some embodiments, R¹ is independently at least one of an alkyl, an alkenyl, an alkoxy, an aryl, a cycloalkyl, or any combination thereof. In some embodiments, n is 0 to 3.

Some embodiments relate to a method. In some embodiments, the method comprises combining, under first reaction conditions, a reagent compound, with a metal alkoxide compound or a hydroxyl-containing compound, and a solvent, to obtain a first reaction product. In some embodiments, the reagent compound comprises a compound of the formula:

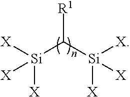

In some embodiments, X is independently a halide. In some embodiments, R¹ is independently at least one of an alkyl, an alkenyl, an alkoxy, an aryl, a cycloalkyl, or any combination thereof. In some embodiments, n is 0 to 3. In some embodiments, the first reaction product comprises a compound of the formula:

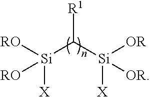

In some embodiments, X is independently a halide. In some embodiments, R is independently a hydrogen or an alkyl, or two of the R attached to the Si are bonded to form a heterocyclic ring. In some embodiments, R¹ is independently at least one of an alkyl, an alkenyl, an alkoxy, an aryl, a cycloalkyl, or any combination thereof. In some embodiments, n is 0 to 3. In some embodiments, the method comprises combining, under second reaction conditions, a base compound with the first reaction product to form a precursor. In some embodiments, the precursor comprises a compound of the formula:

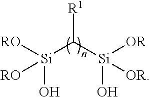

In some embodiments, R is independently a hydrogen or an alkyl, or two of the R attached to the Si are bonded to form a heterocyclic ring. In some embodiments, R¹ is independently at least one of an alkyl, an alkenyl, an alkoxy, an aryl, a cycloalkyl, or any combination thereof. In some embodiments, n is 0 to 3.

Some embodiments relate to an article. In some embodiments, the article comprises a substrate. In some embodiments, the article comprises a film located on the substrate. In some embodiments, the film comprises a reaction product of a precursor and a co-reactant, optionally in a presence of a catalyst. In some embodiments, the precursor comprises a compound of the formula:

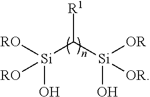

In some embodiments, R is independently a hydrogen or an alkyl, or two of the R attached to the Si are bonded to form a heterocyclic ring. In some embodiments, R¹ is independently at least one of an alkyl, an alkenyl, an alkoxy, an aryl, a cycloalkyl, or any combination thereof. In some embodiments, n is 0 to 3.

### BRIEF DESCRIPTION OF THE DRAWINGS

FIG. 1 is a flowchart of a method for forming a precursor, according to some embodiments.

FIG. 2 is a flowchart of a method for forming a film, according to some embodiments.

FIG. 3 is a 1H NMR spectra for a compound of Example 1, according to some embodiments.

FIG. 4 is a 1H NMR spectra for a compound of Example 2, according to some embodiments.

FIG. 5 is a TGA analysis for a compound of Example 2, according to some embodiments.

FIG. 6 is a 1H NMR spectra for a compound of Example 3, according to some embodiments.

FIG. 7 is a TGA analysis for a compound of Example 3, according to some embodiments.

### DETAILED DESCRIPTION

As used herein, the term “contacting” refers to bringing two or more components into immediate or close proximity, or into direct contact.

As used herein, the term “alkyl” refers to a hydrocarbyl having from 1 to 30 carbon atoms. The alkyl may be attached via a single bond. An alkyl having n carbon atoms may be designated as a “Cₙ alkyl.” For example, a “C₃ alkyl” may include n-propyl and isopropyl. An alkyl having a range of carbon atoms, such as 1 to 30 carbon atoms, may be designated as a C₁-C₃₀ alkyl. In some embodiments, the alkyl is linear. In some embodiments, the alkyl is branched. In some embodiments, the alkyl is substituted. In some embodiments, the alkyl is unsubstituted. In some embodiments, the alkyl comprises or is selected from the group consisting of at least one of a C₁-C₃₀ alkyl, C₁-C₂₉ alkyl, C₁-C₂₈ alkyl, C₁-C₂₇ alkyl, C₁-C₂₇ alkyl, C₁-C₂₆ alkyl, C₁-C₂₅ alkyl, C₁-C₂₄ alkyl, C₁-C₂₃ alkyl, C₁-C₂₂ alkyl, C₁-C₂₁ alkyl, C₁-C₂₀ alkyl, C₁-C₁₉ alkyl, C₁-C₁₈ alkyl, C₁-C₁₇ alkyl, C₁-C₁₆ alkyl, C₁-C₁₅ alkyl, C₁-C₁₄ alkyl, C₁-C₁₃ alkyl, C₁-C₁₂ alkyl, C₁-C₁₁ alkyl, C₁-C₁₀ alkyl, a C₁-C₉ alkyl, a C₁-C₈ alkyl, a C₁-C₇ alkyl, a C₁-C₆ alkyl, a C₁-C₅ alkyl, a C₁-C₄ alkyl, a C₁-C₃ alkyl, a C₁-C₂ alkyl, a C₂-C₃₀ alkyl, a C₃-C₃₀ alkyl, a C₄-C₃₀ alkyl, a C₅-C₃₀ alkyl, a C₆-C₃₀ alkyl, a C₇-C₃₀ alkyl, a C₈-C₃₀ alkyl, a C₉-C₃₀ alkyl, a C₁₀-C₃₀ alkyl, a C₁₁-C₃₀ alkyl, a C₁₂-C₃₀ alkyl, a C₁₃-C₃₀ alkyl, a C₁₄-C₃₀ alkyl, a C₁₅-C₃₀ alkyl, a C₁₆-C₃₀ alkyl, a C₁₇-C₃₀ alkyl, a C₁₈-C₃₀ alkyl, a C₁₉-C₃₀ alkyl, a C₂₀-C₃₀ alkyl, a C₂₁-C₃₀ alkyl, a C₂₂-C₃₀ alkyl, a C₂₃-C₃₀ alkyl, a C₂₄-C₃₀ alkyl, a C₂₅-C₃₀ alkyl, a C₂₆-C₃₀ alkyl, a C₂₇-C₃₀ alkyl, a C₂₈-C₃₀ alkyl, a C₂₉-C₃₀ alkyl, a C₂-C₁₀ alkyl, a C₃-C₁₀ alkyl, a C₄-C₁₀ alkyl, a C₅-C₁₀ alkyl, a C₆-C₁₀ alkyl, a C₇-C₁₀ alkyl, a C₈-C₁₀ alkyl, a C₂-C₉ alkyl, a C₂-C₈ alkyl, a C₂-C₇ alkyl, a C₂-C₆ alkyl, a C₂-C₅ alkyl, a C₃-C₅ alkyl, or any combination thereof. In some embodiments, the alkyl comprises or is selected from the group consisting of at least one of methyl, ethyl, n-propyl, 1-methylethyl (iso-propyl), n-butyl, iso-butyl, sec-butyl, n-pentyl, 1,1-dimethylethyl (t-butyl), n-pentyl, iso-pentyl, n-hexyl, isohexyl, 3-methylhexyl, 2-methylhexyl, heptyl, octyl, nonyl, decyl, dodecyl, octadecyl, or any combination thereof.

As used herein, the term “alkenyl” refers to a hydrocarbyl having from 2 to 30 carbon atoms and at least one carbon-carbon double bond. In some embodiments, the alkenyl comprises or is selected from the group consisting of at least one of a C₂-C₃₀ alkenyl, C₂-C₂₉ alkenyl, C₂-C₂₈ alkenyl, C₂-C₂₇ alkenyl, C₂-C₂₇ alkenyl, C₂-C₂₆ alkenyl, C₂-C₂₅ alkenyl, C₂-C₂₄ alkenyl, C₂-C₂₃ alkenyl, C₂-C₂₂ alkenyl, C₂-C₂₁ alkenyl, C₂-C₂₀ alkenyl, C₂-C₁₉ alkenyl, C₂-C₁₈ alkenyl, C₂-C₁₇ alkenyl, C₂-C₁₆ alkenyl, C₂-C₁₅ alkenyl, C₂-C₁₄ alkenyl, C₂-C₁₃ alkenyl, C₂-C₁₂ alkenyl, C₂-C₁₁ alkenyl, C₂-C₁₀ alkenyl, a C₂-C₉ alkenyl, a C₂-C₈ alkenyl, a C₂-C₇ alkenyl, a C₂-C₆ alkenyl, a C₂-C₅ alkenyl, a C₂-C₄ alkenyl, a C₂-C₃ alkenyl, a C₂ alkenyl, a C₂-C₃₀ alkenyl, a C₃-C₃₀ alkenyl, a C₄-C₃₀ alkenyl, a C₅-C₃₀ alkenyl, a C₆-C₃₀ alkenyl, a C₇-C₃₀ alkenyl, a C₈-C₃₀ alkenyl, a C₉-C₃₀ alkenyl, a C₁₀-C₃₀ alkenyl, a C₁₁-C₃₀ alkenyl, a C₁₂-C₃₀ alkenyl, a C₁₃-C₃₀ alkenyl, a C₁₄-C₃₀ alkenyl, a C₁₅-C₃₀ alkenyl, a C₁₆-C₃₀ alkenyl, a C₁₇-C₃₀ alkenyl, a C₁₈-C₃₀ alkenyl, a C₁₉-C₃₀ alkenyl, a C₂₀-C₃₀ alkenyl, a C₂₁-C₃₀ alkenyl, a C₂₂-C₃₀ alkenyl, a C₂₃-C₃₀ alkenyl, a C₂₄-C₃₀ alkenyl, a C₂₅-C₃₀ alkenyl, a C₂₆-C₃₀ alkenyl, a C₂₇-C₃₀ alkenyl, a C₂₈-C₃₀ alkenyl, a C₂₉-C₃₀ alkenyl, a C₂-C₁₀ alkenyl, a C₃-C₁₀ alkenyl, a C₄-C₁₀ alkenyl, a C₅-C₁₀ alkenyl, a C₆-C₁₀ alkenyl, a C₇-C₁₀ alkenyl, a C₈-C₁₀ alkenyl, a C₂-C₉ alkenyl, a C₂-C₈ alkenyl, a C₂-C₇ alkenyl, a C₂-C₆ alkenyl, a C₂-C₅ alkenyl, a C₃-C₅ alkenyl, or any combination thereof. Examples of alkenyl groups include, without limitation, at least one of vinyl, allyl, 1-methylvinyl, 1-propenyl, 1-butenyl, 2-butenyl, 3-butenyl, 1,3-butadienyl, 2-methyl-1-propenyl, 2-methyl-2-propenyl, 1-pentenyl, 2-pentenyl, 3-pentenyl, 4-pentenyl, 1,3-pentadienyl, 2,4-pentadienyl, 1,4-pentadienyl, 3-methyl-2-butenyl, 1-hexenyl, 2-hexenyl, 3-hexenyl, 1,3-hexadienyl, 1,4-hexadienyl, 2-methylpentenyl, 1-heptenyl, 3-heptenyl, 1-octenyl, 1,3-octadienyl, 1-nonenyl, 2-nonenyl, 3-nonenyl, 1-decenyl, 3-decenyl, 1-undecenyl, oleyl, linoleyl, linolenyl, or any combination thereof.

As used herein, the term “cycloalkyl” refers to a non-aromatic carbocyclic ring having from 3 to 8 carbon atoms in the ring. The term includes a monocyclic non-aromatic carbocyclic ring and a polycyclic non-aromatic carbocyclic ring. The term “monocyclic,” when used as a modifier, refers to a cycloalkyl having a single cyclic ring structure. The term “polycyclic,” when used as a modifier, refers to a cycloalkyl having more than one cyclic ring structure, which may be fused, bridged, spiro, or otherwise bonded ring structures. For example, two or more cycloalkyls may be fused, bridged, or fused and bridged to obtain the polycyclic non-aromatic carbocyclic ring. In some embodiments, the cycloalkyl may comprise, consist of, or consist essentially of, or may be selected from the group consisting of, at least one of cyclopropyl, cyclobutyl, cyclopentyl, cyclohexyl, cycloheptyl, cyclooctyl, or any combination thereof.

As used herein, the term “aryl” refers to a monocyclic or polycyclic aromatic hydrocarbon. The number of carbon atoms of the aryl may be in a range of 5 carbon atoms to 100 carbon atoms. In some embodiments, the aryl has 5 to 20 carbon atoms. For example, in some embodiments, the aryl has 6 to 8 carbon atoms, 6 to 10 carbon atoms, 6 to 12 carbon atoms, 6 to 15 carbon atoms, or 6 to 20 carbon atoms. The term “monocyclic,” when used as a modifier, refers to an aryl having a single aromatic ring structure. The term “polycyclic,” when used as a modifier, refers to an aryl having more than one aromatic ring structure, which may be fused, bridged, spiro, or otherwise bonded ring structures. In some embodiments, the aryl is —C₆H₅.

Non-limiting examples of aryls include, without limitation, at least one of benzene, toluene, xylene (e.g., o-xylene, m-xylene, p-xylene), t-butyltoluene (e.g., o-t-butyltoluene, m-t-butyltoluene, p-t-butyltoluene), ethylmethylbenzene (e.g., 1-ethyl-4-methylbenzene, 1-ethyl-3-methylbenzene), 1-isopropyl-4-methylbenzene, 1-t-butyl-4-methylbenzene, mesitylene, pseudocumene, durene, methylbenzene, dimethylbenzene, trimethylbenzene, ethylbenzene, diethylbenzene (e.g., 1,4-diethylbenzene), triethylbenzene, propylbenzene, butylbenzene, iso-butylbenzene, sec-butylbenzene, t-butylbenzene, hexylbenzene, styrene, naphthalene, anthracene, phenanthrene, biphenyl, terphenyl, methylnaphthalene, biphenylene, dimethylnaphthalene, methylanthracene, 4,4′-dimethylbiphenyl, bibenzyl, diphenylmethane, any isomer thereof, or any combination thereof, and the like.

As used herein, the term “alkoxy” refers to a functional group of formula-OR^{c}, wherein R^{c} is an alkyl (as defined herein), a silylalkyl, a cycloalkyl, or an aryl. In some embodiments, the alkoxy may comprise, consist of, or consist essentially of, or may selected from the group consisting of, at least one of methoxy, ethoxy, n-propoxy, 1-methylethoxy (isopropoxy), n-butoxy, iso-butoxy, sec-butoxy, tert-butoxy, or any combination thereof.

As used herein, the term “halide” refers to a —Cl, —Br, —I, or —F.

As used herein, the term “metal” refers to at least one of an alkali metal, an alkaline earth metal, a transition metal, a post-transition metal, or any combination thereof. In some embodiments, the metal comprises at least one of a lithium, a sodium, a potassium, a rubidium, a cesium, a francium, a beryllium, a magnesium, a calcium, a strontium, a barium, a radium, a scandium, a titanium, a vanadium, a chromium, a manganese, an iron, a cobalt, a nickel, a copper, a zinc, a yttrium, a zirconium, a niobium, a molybdenum, a technetium, a ruthenium, a rhodium, a palladium, a silver, a cadmium, a hafnium, a tantalum, a tungsten, a rhenium, an osmium, an iridium, a platinum, a gold, a mercury, an aluminum, a gallium, an indium, tin, a thallium, a lead, a bismuth, a polonium, or any combination thereof. For example, in some embodiments, the metal comprises at least one of a sodium, a potassium, a lithium, or any combination thereof. In some embodiments, the metal is a counter cation.

As used herein, the term “silicon-containing film” refers to a film comprising at least one of silicon, silicon nitride, silicon oxynitride, silicon oxide, silicon dioxide, silicon carbide, silicon carbonitride, silicon oxycarbonitride, carbon-doped silicon nitride, carbon-doped silicon oxide, carbon-doped silicon oxynitride, or any combination thereof. For example, the silicon-containing film may comprise at least one of a SiO₂ film, a SiO film, a SiN film, a SiOC film, a SiCN film, a SiOCN film, or any combination thereof. In some embodiments, the silicon-containing film has a thickness of 20 Å to 2000 Å.

Some embodiments relate to precursors and related methods. At least some of these embodiments relate to precursors useful in the fabrication of microelectronic devices, including semiconductor devices, and the like. For example, the precursors can be used to form silicon-containing films by one or more deposition processes. Examples of deposition processes include, without limitation, at least one of a metal-catalyzed deposition process, a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

The precursors disclosed herein can be present in a liquid phase at delivery conditions, unlike conventional precursors. The precursors disclosed herein can exhibit increased growth and deposition rates when used in deposition processes for thin film formation, among other things, as compared to conventional precursors. The precursors disclosed herein do not comprise halides, thereby improving quality of resulting film, as compared to conventional precursors. The precursors disclosed herein can result in films with fewer impurities, thereby also improving quality of resulting film, as compared to conventional precursors. The precursors disclosed herein can exhibit higher thermal stability at elevated temperatures as compared to conventional precursors. The precursors disclosed herein can exhibit higher reactivity in, for example, siloxane polymerization reactions, as compared to conventional precursors. The precursors disclosed herein can be useful in the formation, via for example an aluminum-catalyzed silicon deposition process and other deposition processes, of silicon-containing films, including, for example and without limitation, films comprising at least one of SiO₂, SiN, SiOC, SiCN, SiOCN, or any combination thereof, among others as disclosed herein.

In some embodiments, the composition comprises a precursor. In some embodiments, the precursor comprises a silicon-containing precursor. In some embodiments, the precursor comprises a compound of the formula:

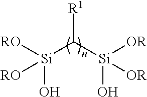

where:
R is independently a hydrogen or an alkyl, or two of the R attached to the Si are bonded to form a heterocyclic ring;
R¹ is independently at least one of an alkyl, an alkenyl, an alkoxy, an aryl, a cycloalkyl, or any combination thereof; and
n is 0 to 3.

In some embodiments, each R on at least one of the Si is the same. In some embodiments, each R on at least one of the Si is different. In some embodiments, all R are the same on the precursor. In some embodiments, at least two R are different on the precursor.

In some embodiments, n is 0, R is a hydrogen, and R¹ is an alkyl. In some embodiments, n is 0, R is a hydrogen, and R¹ is an alkenyl. In some embodiments, n is 0, R is a hydrogen, and R¹ is an alkoxy. In some embodiments, n is 0, R is a hydrogen, and R¹ is an aryl. In some embodiments, n is 0, R is a hydrogen, and R¹ is an cycloalkyl.

In some embodiments, n is 0, R is a linear alkyl, and R¹ is an alkyl. In some embodiments, n is 0, R is a linear alkyl, and R¹ is an alkenyl. In some embodiments, n is 0, R is a linear alkyl, and R¹ is an alkoxy. In some embodiments, n is 0, R is a linear alkyl, and R¹ is an aryl. In some embodiments, n is 0, R is a linear alkyl, and R¹ is an cycloalkyl.

In some embodiments, n is 0, R is a branched alkyl, and R¹ is an alkyl. In some embodiments, n is 0, R is a branched alkyl, and R¹ is an alkenyl. In some embodiments, n is 0, R is a branched alkyl, and R¹ is an alkoxy. In some embodiments, n is 0, R is a branched alkyl, and R¹ is an aryl. In some embodiments, n is 0, R is a branched alkyl, and R¹ is an cycloalkyl.

In some embodiments, n is 0, two of R, which are attached to a Si, are bonded to form a heterocyclic ring, and R¹ is an alkyl. In some embodiments, n is 0, two of R, which are attached to a Si, are bonded to form a heterocyclic ring, and R¹ is an alkenyl. In some embodiments, n is 0, two of R, which are attached to a Si, are bonded to form a heterocyclic ring, and R¹ is an alkoxy. In some embodiments, n is 0, two of R, which are attached to a Si, are bonded to form a heterocyclic ring, and R¹ is an aryl. In some embodiments, n is 0, two of R, which are attached to a Si, are bonded to form a heterocyclic ring, and R¹ is an cycloalkyl.

In some embodiments, n is 1, R is a hydrogen, and R¹ is an alkyl. In some embodiments, n is 1, R is a hydrogen, and R¹ is an alkenyl. In some embodiments, n is 1, R is a hydrogen, and R¹ is an alkoxy. In some embodiments, n is 1, R is a hydrogen, and R¹ is an aryl. In some embodiments, n is 1, R is a hydrogen, and R¹ is an cycloalkyl.

In some embodiments, n is 1, R is a linear alkyl, and R¹ is an alkyl. In some embodiments, n is 1, R is a linear alkyl, and R¹ is an alkenyl. In some embodiments, n is 1, R is a linear alkyl, and R¹ is an alkoxy. In some embodiments, n is 1, R is a linear alkyl, and R¹ is an aryl. In some embodiments, n is 1, R is a linear alkyl, and R¹ is an cycloalkyl.

In some embodiments, n is 1, R is a branched alkyl, and R¹ is an alkyl. In some embodiments, n is 1, R is a branched alkyl, and R¹ is an alkenyl. In some embodiments, n is 1, R is a branched alkyl, and R¹ is an alkoxy. In some embodiments, n is 1, R is a branched alkyl, and R¹ is an aryl. In some embodiments, n is 1, R is a branched alkyl, and R¹ is an cycloalkyl.

In some embodiments, n is 1, two of R, which are attached to a Si, are bonded to form a heterocyclic ring, and R¹ is an alkyl. In some embodiments, n is 1, two of R, which are attached to a Si, are bonded to form a heterocyclic ring, and R¹ is an alkenyl. In some embodiments, n is 1, two of R, which are attached to a Si, are bonded to form a heterocyclic ring, and R¹ is an alkoxy. In some embodiments, n is 1, two of R, which are attached to a Si, are bonded to form a heterocyclic ring, and R¹ is an aryl. In some embodiments, n is 1, two of R, which are attached to a Si, are bonded to form a heterocyclic ring, and R¹ is an cycloalkyl.

In some embodiments, n is 2, R is a hydrogen, and R¹ is an alkyl. In some embodiments, n is 2, R is a hydrogen, and R¹ is an alkenyl. In some embodiments, n is 2, R is a hydrogen, and R¹ is an alkoxy. In some embodiments, n is 2, R is a hydrogen, and R¹ is an aryl. In some embodiments, n is 2, R is a hydrogen, and R¹ is an cycloalkyl.

In some embodiments, n is 2, R is a linear alkyl, and R¹ is an alkyl. In some embodiments, n is 2, R is a linear alkyl, and R¹ is an alkenyl. In some embodiments, n is 2, R is a linear alkyl, and R¹ is an alkoxy. In some embodiments, n is 2, R is a linear alkyl, and R¹ is an aryl. In some embodiments, n is 2, R is a linear alkyl, and R¹ is an cycloalkyl.

In some embodiments, n is 2, R is a branched alkyl, and R¹ is an alkyl. In some embodiments, n is 2, R is a branched alkyl, and R¹ is an alkenyl. In some embodiments, n is 2, R is a branched alkyl, and R¹ is an alkoxy. In some embodiments, n is 2, R is a branched alkyl, and R¹ is an aryl. In some embodiments, n is 2, R is a branched alkyl, and R¹ is an cycloalkyl.

In some embodiments, n is 2, two of R, which are attached to a Si, are bonded to form a heterocyclic ring, and R¹ is an alkyl. In some embodiments, n is 2, two of R, which are attached to a Si, are bonded to form a heterocyclic ring, and R¹ is an alkenyl. In some embodiments, n is 2, two of R, which are attached to a Si, are bonded to form a heterocyclic ring, and R¹ is an alkoxy. In some embodiments, n is 2, two of R, which are attached to a Si, are bonded to form a heterocyclic ring, and R¹ is an aryl. In some embodiments, n is 2, two of R, which are attached to a Si, are bonded to form a heterocyclic ring, and R¹ is an cycloalkyl.

In some embodiments, n is 3, R is a hydrogen, and R¹ is an alkyl. In some embodiments, n is 3, R is a hydrogen, and R¹ is an alkenyl. In some embodiments, n is 3, R is a hydrogen, and R¹ is an alkoxy. In some embodiments, n is 3, R is a hydrogen, and R¹ is an aryl. In some embodiments, n is 3, R is a hydrogen, and R¹ is an cycloalkyl.

In some embodiments, n is 3, R is a linear alkyl, and R¹ is an alkyl. In some embodiments, n is 3, R is a linear alkyl, and R¹ is an alkenyl. In some embodiments, n is 3, R is a linear alkyl, and R¹ is an alkoxy. In some embodiments, n is 3, R is a linear alkyl, and R¹ is an aryl. In some embodiments, n is 3, R is a linear alkyl, and R¹ is an cycloalkyl.

In some embodiments, n is 3, R is a branched alkyl, and R¹ is an alkyl. In some embodiments, n is 3, R is a branched alkyl, and R¹ is an alkenyl. In some embodiments, n is 3, R is a branched alkyl, and R¹ is an alkoxy. In some embodiments, n is 3, R is a branched alkyl, and R¹ is an aryl. In some embodiments, n is 3, R is a branched alkyl, and R¹ is an cycloalkyl.

In some embodiments, n is 3, two of R, which are attached to a Si, are bonded to form a heterocyclic ring, and R¹ is an alkyl. In some embodiments, n is 3, two of R, which are attached to a Si, are bonded to form a heterocyclic ring, and R¹ is an alkenyl. In some embodiments, n is 3, two of R, which are attached to a Si, are bonded to form a heterocyclic ring, and R¹ is an alkoxy. In some embodiments, n is 3, two of R, which are attached to a Si, are bonded to form a heterocyclic ring, and R¹ is an aryl. In some embodiments, n is 3, two of R, which are attached to a Si, are bonded to form a heterocyclic ring, and R¹ is an cycloalkyl.

In some embodiments, R¹ is not hydrogen.

In some embodiments, the precursor comprises at least one of:

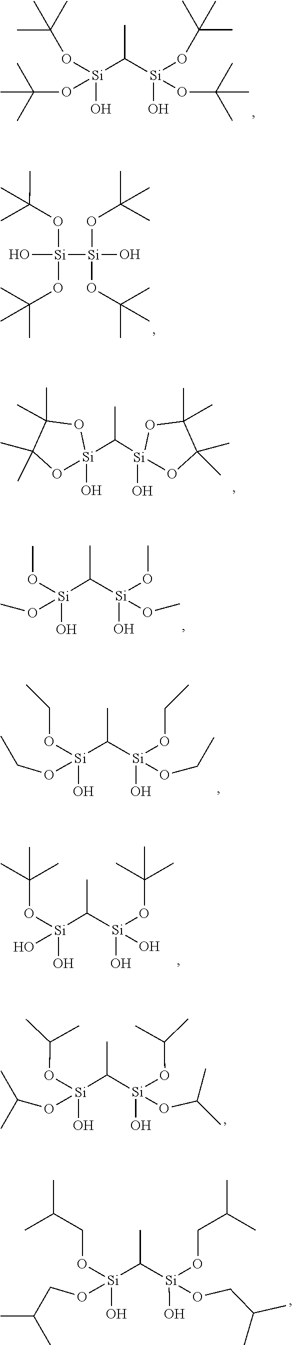

or any combination thereof.

In some embodiments, the precursor is present in the composition at a purity of at least 90% as determined by 1H NMR. For example, in some embodiments, the precursor is present in the composition at a purity of 90% to 99.9999%, 91% to 99.9999%, 92% to 99.9999%, 93% to 99.9999%, 94% to 99.9999%, 95% to 99.9999%, 96% to 99.9999%, 97% to 99.9999%, 98% to 99.9999%, 99% to 99.9999%, 99.9% to 99.9999%, 99.99% to 99.9999%, 99.999% to 99.9999%, 90% to 99.999%, 90% to 99.99%, 90% to 99.9%, 90% to 99%, 90% to 98%, 90% to 97%, 90% to 96%, 90% to 95%, 90% to 94%, 90% to 93%, 90% to 92%, or 90% to 91%.

In some embodiments, when the precursor is exposed to a substrate, and optionally at least a catalyst (e.g., an aluminum catalyst), under deposition conditions, the precursor forms a film having less than 10% by weight of an impurity based on a total weight of the film, or any range or subrange between 0.001% and 10%. For example, in some embodiments, when the precursor is exposed to a substrate, and optionally a catalyst, under deposition conditions, the precursor forms a film having less than 10%, less than 9%, less than 8%, less than 7%, less than 6%, less than 5%, less than 4%, less than 3%, less than 2%, less than 1%, less than 0.1%, or less than 0.01% by weight of an impurity based on a total weight of the film.

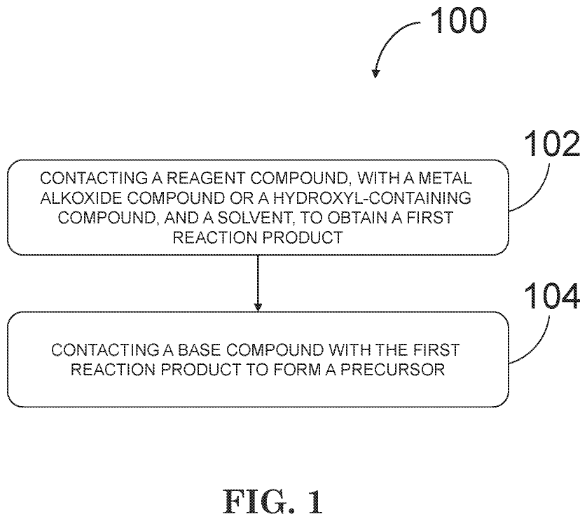

FIG. 1 is a flowchart of a method for forming a precursor, according to some embodiments. As shown in FIG. 1, in some embodiments, the method for forming a precursor comprises one or more of the following steps, in any order: contacting 102, under first reaction conditions, a reagent compound, with a metal alkoxide compound or a hydroxyl-containing compound, and a solvent, to obtain a first reaction product; and contacting 104, under second reaction conditions, a base compound with the first reaction product to form a precursor. In some embodiments, the method for forming the precursor does not comprise step 102. In some embodiments, the method for forming the precursor does not comprise step 104.

At step 102, in some embodiments, the method for forming a precursor comprises contacting, under first reaction conditions, a reagent compound, with a metal alkoxide compound or a hydroxyl-containing compound, and a solvent, to obtain a first reaction product.

The contacting can comprise bringing at least one of the reagent compound, the metal alkoxide compound, the hydroxyl-containing compound, the solvent, or any combination thereof, into immediate or close proximity, or direct contact. For example, in some embodiments, the contacting comprises combining at least one of the reagent compound, the metal alkoxide compound, the hydroxyl-containing compound, the solvent, or any combination thereof, in a reaction vessel. In some embodiments, the contacting comprises mixing at least one of the reagent compound, the metal alkoxide compound, the hydroxyl-containing compound, the solvent, or any combination thereof. In some embodiments, the contacting comprises stirring at least one of the reagent compound, the metal alkoxide compound, the hydroxyl-containing compound, the solvent, or any combination thereof. In some embodiments, the contacting comprises agitating at least one of the reagent compound, the metal alkoxide compound, the hydroxyl-containing compound, the solvent, or any combination thereof. In some embodiments, the contacting comprises adding, in any order, at least one of the reagent compound, the metal alkoxide compound, the hydroxyl-containing compound, the solvent, or any combination thereof, to a reaction vessel.

The contacting under the first reaction conditions can proceed at a temperature in a range of −20° C. to 100° C., or any range or subrange between-20° C. and 100° C. For example, in some embodiments, the contacting under the first reaction conditions proceeds at a temperature in a range of −20° C. to 90° C., −20° C. to 80° C., −20° C. to 70° C., −20° C. to 60° C., −20° C. to 50° C., −20° C. to 40° C., −20° C. to 30° C., −20° C. to 20° C., −20° C. to 10° C., −20° C. to 0° C., −20° C. to −10° C., −10° C. to 90° C., 0° C. to 90° C. 10° C. to 90° C., 20° C. to 90° C., 30° C. to 90° C., 40° C. to 90° C., 50° C. to 90° C., 60° C. to 90° C., 70° C. to 90° C., or 80° C. to 90° C. In some embodiments, the contacting under the first reaction conditions can proceed at ambient pressure, under vacuum, or under positive pressure.

The reagent compound can comprise a compound of the formula:

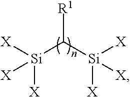

where:
X is independently a halide;
R¹ is independently at least one of an alkyl, an alkenyl, an alkoxy, an aryl, a cycloalkyl, or any combination thereof; and
n is 0 to 3.

In some embodiments, each X on at least one of the Si is the same. In some embodiments, each X on at least one of the Si is different. In some embodiments, all X are the same on the precursor. In some embodiments, at least two X are different on the precursor.

In some embodiments, n is 0 and R¹ is alkyl. In some embodiments, n is 0 and R¹ is alkenyl. In some embodiments, n is 0 and R¹ is alkoxy. In some embodiments, n is 0 and R¹ is aryl. In some embodiments, n is 0 and R¹ is cycloalkyl.

In some embodiments, n is 1 and R¹ is alkyl. In some embodiments, n is 1 and R¹ is alkenyl. In some embodiments, n is 1 and R¹ is alkoxy. In some embodiments, n is 1 and R¹ is aryl. In some embodiments, n is 1 and R¹ is cycloalkyl.

In some embodiments, n is 2 and R¹ is alkyl. In some embodiments, n is 2 and R¹ is alkenyl. In some embodiments, n is 2 and R¹ is alkoxy. In some embodiments, n is 2 and R¹ is aryl. In some embodiments, n is 2 and R¹ is cycloalkyl.

In some embodiments, n is 3 and R¹ is alkyl. In some embodiments, n is 3 and R¹ is alkenyl. In some embodiments, n is 3 and R¹ is alkoxy. In some embodiments, n is 3 and R¹ is aryl. In some embodiments, n is 3 and R¹ is cycloalkyl.

In some embodiments, R¹ is not a hydrogen.

The metal alkoxide compound can comprise a compound of the formula:

M-OR,
where:
M is a metal; and
R is independently at least one of a hydrogen or an alkyl, or two of the R attached to the Si are bonded to form a heterocyclic ring.

In some embodiments, the metal alkoxide compound comprises an alkali metal alkoxide compound. In some embodiments, the metal alkoxide compound comprises an alkaline earth metal alkoxide compound. In some embodiments, the metal alkoxide compound comprises a transition metal alkoxide compound. In some embodiments, the metal alkoxide compound comprises a post-transition metal alkoxide compound. A non-limiting example of a metal alkoxide compound includes, for example and without limitation, a potassium tert-butoxide compound, a sodium methoxide, a sodium ethoxide, a sodium isopropoxide, a sodium isobutoxide, and the like, among others.

The hydroxyl-containing compound can comprise a compound comprising at least one hydroxyl. In some embodiments, the hydroxyl-containing compound comprises at least two hydroxyls, or more, for example, three hydroxyls, four hydroxyls, etc. For example, in some embodiments, the hydroxyl-containing compound can be used to form a reaction product or a precursor in which two of the R attached to at least one of the Si are bonded to form a heterocyclic ring. In some embodiments, the hydroxyl-containing compound comprises an alcohol, such as, for example and without limitation, a diol compound or other polyol compound. In some embodiments, the hydroxy-containing compound comprises a compound of the formula:

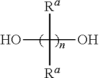

where:
R^{a} independently comprises a hydrogen or an alkyl;
n is at least 1.

It will be appreciated that, when n is 2 or more, R^{a} can be independently a hydrogen or an alkyl with respect to those R^{a} attached to the same carbon atom, and can also be independently a hydrogen or an alkyl with respect to R^{a} attached to different carbon atoms. In some embodiments, when the hydroxyl-containing compound is used, the precursor is formed without forming the first reaction product. In some embodiments, when the hydroxyl-containing compound is used, the precursor is formed as a rection product of the step 102. In some embodiments, when the hydroxyl-containing compound is used, the step 104 is not required, nor performed.

With respect to the R^{a} attached to the same carbon atom, in some embodiments, each R^{a} is the same. In some embodiments, each R^{a} is different. In some embodiments, R^{a} comprises the hydrogen. In some embodiments, the R^{a} comprises the alkyl.

With respect to the R^{a} attached to different carbon atoms (e.g., when n is 2 or more), in some embodiments, at least two R^{a} are the same. In some embodiments, at least two R^{a} are different. In some embodiments, R^{a} comprises hydrogen. In some embodiments, R^{a} comprises alkyl. In some embodiments, R^{a} comprises hydrogen and alkyl.

In some embodiments, n is 1 to 10, 1 to 9, 1 to 8, 1 to 7, 1 to 6, 1 to 5, 1 to 4, 1 to 3, 1 to 2, 2 to 10, 3 to 10, 4 to 10, 4 to 10, 5 to 10, 6 to 10, 7 to 10, 8 to 10, or 9 to 10. In some embodiments, R^{a} comprises a hydrogen and an alkyl. In some embodiments, R^{a} comprises hydrogen. In some embodiments, R^{a} comprises an alkyl.

In some embodiments, the hydroxyl-containing compound comprises a compound of the formula:

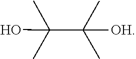

The solvent can comprise a non-polar solvent, such as, for example and without limitation, at least one of dichloromethane (DCM), diethyl ether, tetrahydrofuran (THF), n-hexane, heptane, toluene, benzene, cyclohexane, or any combination thereof. In some embodiments, the solvent comprises a water.

The first reaction product can comprise a compound of the formula:

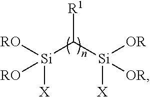

where:
X is independently a halide;
R is independently a hydrogen or an alkyl, or two of the R attached to the Si are bonded to form a heterocyclic ring;
R¹ is independently at least one of an alkyl, an alkenyl, an alkoxy, an aryl, a cycloalkyl, or any combination thereof; and
n is 0 to 3.

In some embodiments, each X is the same. In some embodiments, each X is different. In some embodiments, each R on at least one of the Si is the same. In some embodiments, each R on at least one of the Si is different. In some embodiments, all R are the same on the precursor. In some embodiments, at least two R are different on the precursor.

In some embodiments, n is 0, X is a halide, R is a hydrogen, and R¹ is an alkyl. In some embodiments, n is 0, X is a halide, R is a hydrogen, and R¹ is an alkenyl. In some embodiments, n is 0, X is a halide, R is a hydrogen, and R¹ is an alkoxy. In some embodiments, n is 0, X is a halide, R is a hydrogen, and R¹ is an aryl. In some embodiments, n is 0, X is a halide, R is a hydrogen, and R¹ is an cycloalkyl.

In some embodiments, n is 0, X is a halide, R is a linear alkyl, and R¹ is an alkyl. In some embodiments, n is 0, X is a halide, R is a linear alkyl, and R¹ is an alkenyl. In some embodiments, n is 0, X is a halide, R is a linear alkyl, and R¹ is an alkoxy. In some embodiments, n is 0, X is a halide, R is a linear alkyl, and R¹ is an aryl. In some embodiments, n is 0, X is a halide, R is a linear alkyl, and R¹ is an cycloalkyl.

In some embodiments, n is 0, X is a halide, R is a branched alkyl, and R¹ is an alkyl. In some embodiments, n is 0, X is a halide, R is a branched alkyl, and R¹ is an alkenyl. In some embodiments, n is 0, X is a halide, R is a branched alkyl, and R¹ is an alkoxy. In some embodiments, n is 0, X is a halide, R is a branched alkyl, and R¹ is an aryl. In some embodiments, n is 0, X is a halide, R is a branched alkyl, and R¹ is an cycloalkyl.

In some embodiments, n is 0, X is a halide, two of R, which are attached to a Si, are bonded to form a heterocyclic ring, and R¹ is an alkyl. In some embodiments, n is 0, X is a halide, two of R, which are attached to a Si, are bonded to form a heterocyclic ring, and R¹ is an alkenyl. In some embodiments, n is 0, X is a halide, two of R, which are attached to a Si, are bonded to form a heterocyclic ring, and R¹ is an alkoxy. In some embodiments, n is 0, X is a halide, two of R, which are attached to a Si, are bonded to form a heterocyclic ring, and R¹ is an aryl. In some embodiments, n is 0, X is a halide, two of R, which are attached to a Si, are bonded to form a heterocyclic ring, and R¹ is an cycloalkyl.

In some embodiments, n is 1, X is a halide, R is a hydrogen, and R¹ is an alkyl. In some embodiments, n is 1, X is a halide, R is a hydrogen, and R¹ is an alkenyl. In some embodiments, n is 1, X is a halide, R is a hydrogen, and R¹ is an alkoxy. In some embodiments, n is 1, X is a halide, R is a hydrogen, and R¹ is an aryl. In some embodiments, n is 1, X is a halide, R is a hydrogen, and R¹ is an cycloalkyl.

In some embodiments, n is 1, X is a halide, R is a linear alkyl, and R¹ is an alkyl. In some embodiments, n is 1, X is a halide, R is a linear alkyl, and R¹ is an alkenyl. In some embodiments, n is 1, X is a halide, R is a linear alkyl, and R¹ is an alkoxy. In some embodiments, n is 1, X is a halide, R is a linear alkyl, and R¹ is an aryl. In some embodiments, n is 1, X is a halide, R is a linear alkyl, and R¹ is an cycloalkyl.

In some embodiments, n is 1, X is a halide, R is a branched alkyl, and R¹ is an alkyl. In some embodiments, n is 1, X is a halide, R is a branched alkyl, and R¹ is an alkenyl. In some embodiments, n is 1, X is a halide, R is a branched alkyl, and R¹ is an alkoxy. In some embodiments, n is 1, X is a halide, R is a branched alkyl, and R¹ is an aryl. In some embodiments, n is 1, X is a halide, R is a branched alkyl, and R¹ is an cycloalkyl.

In some embodiments, n is 1, X is a halide, two of R, which are attached to a Si, are bonded to form a heterocyclic ring, and R¹ is an alkyl. In some embodiments, n is 1, X is a halide, two of R, which are attached to a Si, are bonded to form a heterocyclic ring, and R¹ is an alkenyl. In some embodiments, n is 1, X is a halide, two of R, which are attached to a Si, are bonded to form a heterocyclic ring, and R¹ is an alkoxy. In some embodiments, n is 1, X is a halide, two of R, which are attached to a Si, are bonded to form a heterocyclic ring, and R¹ is an aryl. In some embodiments, n is 1, X is a halide, two of R, which are attached to a Si, are bonded to form a heterocyclic ring, and R¹ is an cycloalkyl.

In some embodiments, n is 2, X is a halide, R is a hydrogen, and R¹ is an alkyl. In some embodiments, n is 2, X is a halide, R is a hydrogen, and R¹ is an alkenyl. In some embodiments, n is 2, X is a halide, R is a hydrogen, and R¹ is an alkoxy. In some embodiments, n is 2, X is a halide, R is a hydrogen, and R¹ is an aryl. In some embodiments, n is 2, X is a halide, R is a hydrogen, and R¹ is an cycloalkyl.

In some embodiments, n is 2, X is a halide, R is a linear alkyl, and R¹ is an alkyl. In some embodiments, n is 2, X is a halide, R is a linear alkyl, and R¹ is an alkenyl. In some embodiments, n is 2, X is a halide, R is a linear alkyl, and R¹ is an alkoxy. In some embodiments, n is 2, X is a halide, R is a linear alkyl, and R¹ is an aryl. In some embodiments, n is 2, X is a halide, R is a linear alkyl, and R¹ is an cycloalkyl.

In some embodiments, n is 2, X is a halide, R is a branched alkyl, and R¹ is an alkyl. In some embodiments, n is 2, X is a halide, R is a branched alkyl, and R¹ is an alkenyl. In some embodiments, n is 2, X is a halide, R is a branched alkyl, and R¹ is an alkoxy. In some embodiments, n is 2, X is a halide, R is a branched alkyl, and R¹ is an aryl. In some embodiments, n is 2, X is a halide, R is a branched alkyl, and R¹ is an cycloalkyl.

In some embodiments, n is 2, X is a halide, two of R, which are attached to a Si, are bonded to form a heterocyclic ring, and R¹ is an alkyl. In some embodiments, n is 2, X is a halide, two of R, which are attached to a Si, are bonded to form a heterocyclic ring, and R¹ is an alkenyl. In some embodiments, n is 2, X is a halide, two of R, which are attached to a Si, are bonded to form a heterocyclic ring, and R¹ is an alkoxy. In some embodiments, n is 2, X is a halide, two of R, which are attached to a Si, are bonded to form a heterocyclic ring, and R¹ is an aryl. In some embodiments, n is 2, X is a halide, two of R, which are attached to a Si, are bonded to form a heterocyclic ring, and R¹ is an cycloalkyl.

In some embodiments, n is 3, X is a halide, R is a hydrogen, and R¹ is an alkyl. In some embodiments, n is 3, X is a halide, R is a hydrogen, and R¹ is an alkenyl. In some embodiments, n is 3, X is a halide, R is a hydrogen, and R¹ is an alkoxy. In some embodiments, n is 3, X is a halide, R is a hydrogen, and R¹ is an aryl. In some embodiments, n is 3, X is a halide, R is a hydrogen, and R¹ is an cycloalkyl.

In some embodiments, n is 3, X is a halide, R is a linear alkyl, and R¹ is an alkyl. In some embodiments, n is 3, X is a halide, R is a linear alkyl, and R¹ is an alkenyl. In some embodiments, n is 3, X is a halide, R is a linear alkyl, and R¹ is an alkoxy. In some embodiments, n is 3, X is a halide, R is a linear alkyl, and R¹ is an aryl. In some embodiments, n is 3, X is a halide, R is a linear alkyl, and R¹ is an cycloalkyl.

In some embodiments, n is 3, X is a halide, R is a branched alkyl, and R¹ is an alkyl. In some embodiments, n is 3, X is a halide, R is a branched alkyl, and R¹ is an alkenyl. In some embodiments, n is 3, X is a halide, R is a branched alkyl, and R¹ is an alkoxy. In some embodiments, n is 3, X is a halide, R is a branched alkyl, and R¹ is an aryl. In some embodiments, n is 3, X is a halide, R is a branched alkyl, and R¹ is an cycloalkyl.

In some embodiments, n is 3, X is a halide, two of R, which are attached to a Si, are bonded to form a heterocyclic ring, and R¹ is an alkyl. In some embodiments, n is 3, X is a halide, two of R, which are attached to a Si, are bonded to form a heterocyclic ring, and R¹ is an alkenyl. In some embodiments, n is 3, X is a halide, two of R, which are attached to a Si, are bonded to form a heterocyclic ring, and R¹ is an alkoxy. In some embodiments, n is 3, X is a halide, two of R, which are attached to a Si, are bonded to form a heterocyclic ring, and R¹ is an aryl. In some embodiments, n is 3, X is a halide, two of R, which are attached to a Si, are bonded to form a heterocyclic ring, and R¹ is an cycloalkyl.

At step 104, in some embodiments, the method for forming a precursor comprises contacting, under second reaction conditions, a base compound with the first reaction product to form a precursor.

The contacting can comprise bringing at least the first reaction product and the base compound into immediate or close proximity, or direct contact. For example, in some embodiments, the contacting comprises combining at least the first reaction product and the base compound in a reaction vessel. In some embodiments, the contacting comprises mixing at least the first reaction product and the base compound. In some embodiments, the contacting comprises stirring at least the first reaction product and the base compound. In some embodiments, the contacting comprises agitating at least the first reaction product and the base compound. In some embodiments, the contacting comprises adding, in any order, at least the first reaction product and the base compound to a reaction vessel.

The contacting under the second reaction conditions can proceed at a temperature in a range of −20° C. to 100° C., or any range or subrange between-20° C. and 100° C. For example, in some embodiments, the contacting under the second reaction conditions proceeds at a temperature in a range of −20° C. to 90° C., −20° C. to 80° C., −20° C. to 70° C., −20° C. to 60° C., −20° C. to 50° C., −20° C. to 40° C., −20° C. to 30° C., −20° C. to 20° C., −20° C. to 10° C., −20° C. to 0° C., −20° C. to −10° C., −10° C. to 90° C., 0° C. to 90° C. 10° C. to 90° C., 20° C. to 90° C., 30° C. to 90° C., 40° C. to 90° C., 50° C. to 90° C., 60° C. to 90° C., 70° C. to 90° C., or 80° C. to 90° C. In some embodiments, the contacting under the second reaction conditions can proceed at ambient pressure, under vacuum, or under positive pressure.

The base compound can comprise an organic base compound. For example, in some embodiments, the base compound comprises an amine compound, such as, for example and without limitation, a triethylamine compound. In some embodiments, the base compound comprises at least one of a triethylamine, a pyridine, a diisopropylethylamine, an imidazole, a benzimidazole, or any combination thereof.

The precursor can comprise any one or more of the precursors disclosed herein. For example, in some embodiments, the precursor comprises a compound of the formula:

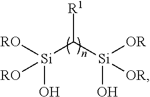

where:
R is independently a hydrogen or an alkyl, or two of the R attached to the Si are bonded to form a heterocyclic ring;
R¹ is independently at least one of an alkyl, an alkenyl, an alkoxy, an aryl, a cycloalkyl, or any combination thereof; and
n is 0 to 3.

For example, in some embodiments, the precursor comprises at least one of:

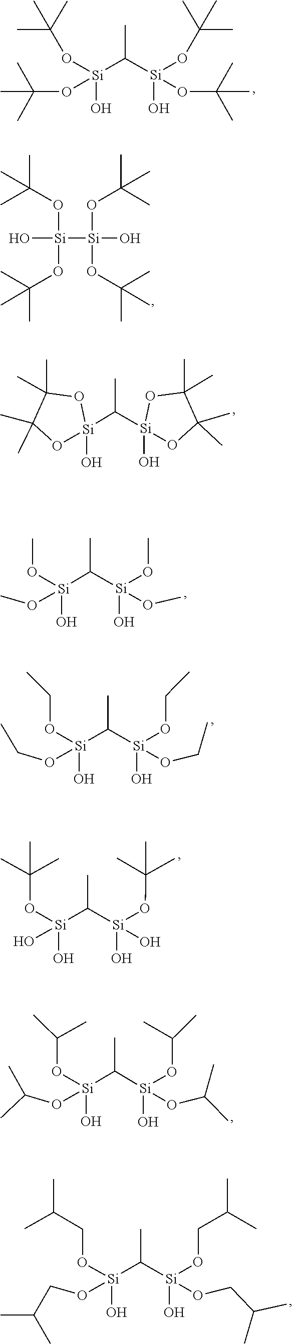

or any combination thereof.

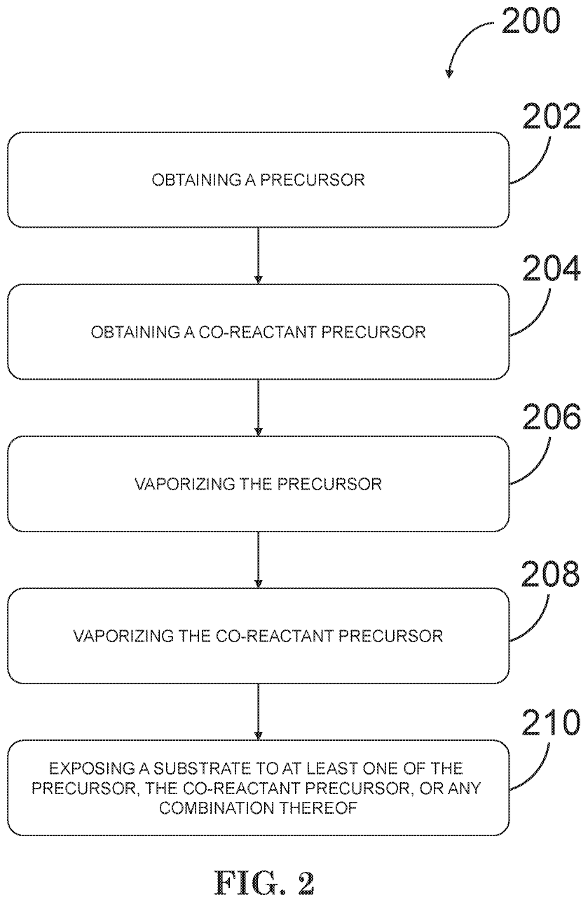

FIG. 2 is a flowchart of a method for forming a film, according to some embodiments. As shown in FIG. 2, in some embodiments, the method for forming a film comprises one or more of the following steps: obtaining 202 a precursor; obtaining 204 a co-reactant precursor; vaporizing 206 the precursor to obtain a vaporized precursor, vaporizing 208 the co-reactant precursor to obtain a vaporized co-reactant precursor, exposing 210, under deposition conditions, a substrate to at least one of the precursor, the at least one co-reactant precursor, or any combination thereof, optionally in a presence of a catalyst, to form a film on the substrate.

At step 202, in some embodiments, the method comprises obtaining a precursor.

In some embodiments, the obtaining comprises obtaining a vessel comprising the precursor. In some embodiments, the obtaining comprises obtaining a container comprising the precursor. In some embodiments, the precursor may be obtained in a container or other vessel configured to deliver the precursor to a substrate for a deposition process. It will be appreciated that the precursor may comprise any one or more of the precursors disclosed herein. For example, in some embodiments, the precursor comprises a compound of the formula:

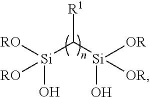

where:
R is independently a hydrogen or an alkyl, or two of the R attached to the Si are bonded to form a heterocyclic ring;
R¹ is independently at least one of an alkyl, an alkenyl, an alkoxy, an aryl, a cycloalkyl, or any combination thereof; and
n is 0 to 3.

At step 204, in some embodiments, the method comprises obtaining at least one co-reactant precursor.

In some embodiments, the at least one co-reactant precursor comprises at least one of an oxidizing gas, a reducing gas, a hydrocarbon, or any combination thereof. The at least one co-reactant precursor may be selected to obtain a desired film. In some embodiments, the at least one co-reactant precursor comprises at least one of N₂, H₂, NH₃, N₂H₄, CH₃HNNH₂, CH₃HNNHCH₃, NCH₃H₂, NCH₃CH₂H₂, N(CH₃)₂H, N(CH₃CH₂)₂H, N(CH₃)₃, N(CH₃CH₂)₃, Si(CH₃)₂NH, pyrazoline, pyridine, ethylene diamine, a radical thereof, or any combination thereof. In some embodiments, the at least one co-reactant precursor comprises at least one of H₂, O₂, O₃, H₂O, H₂O₂, NO, N₂O, NO₂, CO, CO₂, a carboxylic acid, an alcohol, a diol, a radical thereof, or any combination thereof. In some embodiments, the at least one co-reactant precursor comprises at least one of methane, ethane, ethylene, acetylene, or any combination thereof. The obtaining may comprise obtaining a container or other vessel comprising the at least one co-reactant precursor. In some embodiments, the at least one co-reactant precursor may be obtained in a container or other vessel configured to deliver the precursor to a substrate for a deposition process. In some embodiments, the method further comprises an inert gas, such as, for example, at least one of argon, helium, nitrogen, or any combination thereof. In some embodiments, the method does not comprise the step of obtaining the co-reactant precursor.

At step 206, in some embodiments, the method comprises vaporizing the precursor to obtain a vaporized precursor.

In some embodiments, the vaporizing may comprise heating the precursor sufficient to obtain the vaporized precursor. In some embodiments, the vaporizing comprises heating a container comprising the precursor. In some embodiments, the vaporizing comprises heating the precursor in a deposition chamber in which the deposition process is performed. In some embodiments, the vaporizing comprises heating a conduit for delivering the precursor, the vaporized precursor, or any combination thereof to, for example, a deposition chamber. In some embodiments, the vaporizing comprises operating a vapor delivery system comprising the precursor. In some embodiments, the vaporizing comprises heating to a temperature sufficient to vaporize the precursor to obtain the vaporized precursor. In some embodiments, the vaporizing comprises heating to a temperature below a decomposition temperature of at least one of the precursor, the vaporized precursor, or any combination thereof. In some embodiments, the precursor may be present in a gas phase or other vaporizable phase, in which case the step 206 is optional and not required. For example, in some embodiments, the precursor comprises the vaporized precursor. In some embodiments, the method does not comprise the step of vaporizing the precursor to obtain a vaporized precursor.

At step 208, in some embodiments, the method comprises vaporizing the at least one co-reactant precursor to obtain a vaporized co-reactant precursor.

In some embodiments, the vaporizing comprises heating the at least one co-reactant precursor sufficient to obtain the at least one vaporized co-reactant precursor. In some embodiments, the vaporizing comprises heating a container comprising the at least one co-reactant precursor. In some embodiments, the vaporizing comprises heating the at least one co-reactant precursor in a deposition chamber in which the vapor deposition process is performed. In some embodiments, the vaporizing comprises heating a conduit for delivering the at least one co-reactant precursor, the at least one vaporized co-reactant precursor, or any combination thereof to, for example, a deposition chamber. In some embodiments, the vaporizing comprises operating a vapor delivery system comprising the at least one co-reactant precursor. In some embodiments, the vaporizing comprises heating to a temperature sufficient to vaporize the at least one co-reactant precursor to obtain the at least one vaporized co-reactant precursor. In some embodiments, the vaporizing comprises heating to a temperature below a decomposition temperature of at least one of the at least one co-reactant precursor, the at least one vaporized co-reactant precursor, or any combination thereof. In some embodiments, the at least one co-reactant precursor may be present in a gas phase or other vaporizable phase, in which case the step 208 is optional and not required. For example, in some embodiments, the at least one co-reactant precursor comprises the at least one vaporized co-reactant precursor. In some embodiments, the method does not comprise the step of vaporizing the co-reactant precursor to obtain a vaporized co-reactant precursor.

At step 210, in some embodiments, the method comprises exposing 210, under deposition conditions, a substrate to at least one of the precursor, the at least one co-reactant precursor, or any combination thereof, optionally in a presence of a catalyst, to form a film on the substrate.

In some embodiments, the exposing comprises exposing, under deposition conditions, a substrate to at least one of the precursor, the at least one co-reactant precursor, or any combination thereof, optionally in a presence of a catalyst, to form a film on the substrate. In some embodiments, the exposing is conducted while the catalyst is located on the substrate. For example, in some embodiments, the substrate comprises an aluminum catalyst located on the substrate. That is, for example, in some embodiments, the substrate is a substrate that has been formed by depositing aluminum on the substrate to form a film comprising aluminum and heating the film comprising aluminum to at least an aluminum-silicon eutectic temperature. In some embodiments, the step of depositing aluminum on the substrate comprises depositing aluminum via any one or more of the deposition processes disclosed herein. In some embodiments, the step of heating the film comprising aluminum comprises annealing the film comprising aluminum at or above the aluminum-silicon eutectic temperature. It will be appreciated that, although aluminum catalysts are disclosed herein, other catalysts can be employed without departing from the scope of this disclosure. In some embodiments, the deposition process does not involve use of any catalyst.

The exposing may be performed in any system, apparatus, device, assembly, chamber thereof, or component thereof suitable for deposition processes, including, for example and without limitation, a deposition chamber, among others. In some embodiments, the exposing comprises contacting the substrate with at least one of the precursor, the at least one co-reactant precursor, or any combination thereof. The precursor and the at least one co-reactant precursor may be contacted with the substrate at the same time or at different times. For example, each of the precursor, the at least one co-reactant precursor, and the substrate may be present in the deposition chamber at the same time. That is, in some embodiments, the contacting may comprise contemporaneous contacting or simultaneous contacting of the precursor and the at least one co-reactant precursor with the substrate. Alternatively, each of the precursor and the at least one co-reactant precursor may be present in the deposition chamber at different times. That is, in some embodiments, the contacting may comprise alternate and/or sequential contacting, in one or more cycles, of the precursor with the substrate and subsequently contacting the at least one co-reactant precursor with the substrate. In some embodiments, the method does not comprise exposing the substrate to the at least one co-reactant precursor.

The deposition conditions may comprise conditions for vapor deposition processes. Examples of vapor deposition conditions include, without limitation, vapor deposition conditions for vapor deposition processes including at least one of a metal-catalyzed deposition process (e.g., an aluminum-catalyzed silicon deposition process), a chemical vapor deposition (CVD) process, a digital or pulsed chemical vapor deposition process, a plasma-enhanced cyclical chemical vapor deposition process (PECCVD), a flowable chemical vapor deposition process (FCVD), an atomic layer deposition (ALD) process, a thermal atomic layer deposition, a plasma-enhanced atomic layer deposition (PEALD) process, a metal organic chemical vapor deposition (MOCVD) process, a plasma-enhanced chemical vapor deposition (PECVD) process, or any combination thereof.

The deposition conditions may comprise a deposition temperature. The deposition temperature may be a temperature less than the thermal decomposition temperature of at least one of the precursor, the at least one co-reactant precursor, or any combination thereof. The deposition temperature may be sufficiently high to reduce or avoid condensation of at least one of the precursor, the at least one co-reactant precursor, or any combination thereof. In some embodiments, the substrate may be heated to the deposition temperature. In some embodiments, the chamber or other vessel in which the substrate is contacted with the precursor and the at least one co-reactant precursor is heated to the deposition temperature. In some embodiments, at least one of the precursor, the at least one co-reactant precursor, or any combination thereof may be heated to the deposition temperature.

The deposition temperature may be a temperature of 200° C. to 2500° C., or any range or subrange between 200° C. and 2500° C. In some embodiments, the deposition temperature may be a temperature of 500° C. to 700° C. For example, in some embodiments, the deposition temperature may be a temperature of 500° C. to 680° C., 500° C. to 660° C., 500° C. to 640° C., 500° C. to 620° C., 500° C. to 600° C., 500° C. to 580° C., 500° C. to 560° C., 500° C. to 540° C., 500° C. to 520° C., 520° C. to 700° C., 540° C. to 700° C., 560° C. to 700° C., 580° C. to 700° C., 600° C. to 700° C., 620° C. to 700° C., 640° C. to 700° C., 660° C. to 700° C., or 680° C. to 700° C. In other embodiments, the deposition temperature may be a temperature of greater than 200° C. to 2500° C., such as, for example and without limitation, a temperature of 400° C. to 2000, 500° C. to 2000° C., 550° C. to 2400° C., 600° C. to 2400° C., 625° C. to 2400° C., 650° C. to 2400° C., 675° C. to 2400° C., 700° C. to 2400° C., 725° C. to 2400° C., 750° C. to 2400° C., 775° C. to 2400° C., 800° C. to 2400° C., 825° C. to 2400° C., 850° C. to 2400° C., 875° C. to 2400° C., 900° C. to 2400° C., 925° C. to 2400° C., 950° C. to 2400° C., 975° C. to 2400° C., 1000° C. to 2400° C., 1025° C. to 2400° C., 1050° C. to 2400° C., 1075° C. to 2400° C., 1100° C. to 2400° C., 1200° C. to 2400° C., 1300° C. to 2400° C., 1400° C. to 2400° C., 1500° C. to 2400° C., 1600° C. to 2400° C., 1700° C. to 2400° C., 1800° C. to 2400° C., 1900° C. to 2400° C., 2000° C. to 2400° C., 2100° C. to 2400° C., 2200° C. to 2400° C., 2300° C. to 2400° C., 500° C. to 2000° C., 500° C. to 1900° C., 500° C. to 1800° C., 500° C. to 1700° C., 500° C. to 1600° C., 500° C. to 1500° C., 500° C. to 1400° C., 500° C. to 1300° C., 500° C. to 1200° C., 500° C. to 1100° C., 500° C. to 1000° C., 500° C. to 1000° C., 500° C. to 900° C., or 500° C. to 800° C.

The deposition conditions may comprise a deposition pressure. In some embodiments, the deposition pressure may comprise a vapor pressure of at least one of the precursor, the at least one co-reactant precursor, or any combination thereof. In some embodiments, the deposition pressure may comprise a chamber pressure.

The deposition pressure may be a pressure of 0.001 Torr to 100 Torr, or any range or subrange between 0.001 Torr and 100 Torr. For example, in some embodiments, the deposition pressure may be a pressure of 1 Torr to 30 Torr, 1 Torr to 25 Torr, 1 Torr to 20 Torr, 1 Torr to 15 Torr, 1 Torr to 10 Torr, 5 Torr to 50 Torr, 5 Torr to 40 Torr, 5 Torr to 30 Torr, 5 Torr to 20 Torr, or 5 Torr to 15 Torr. In other embodiments, the deposition pressure may be a pressure of 1 Torr to 100 Torr, 5 Torr to 100 Torr, 10 Torr to 100 Torr, 15 Torr to 100 Torr, 20 Torr to 100 Torr, 25 Torr to 100 Torr, 30 Torr to 100 Torr, 35 Torr to 100 Torr, 40 Torr to 100 Torr, 45 Torr to 100 Torr, 50 Torr to 100 Torr, 55 Torr to 100 Torr, 60 Torr to 100 Torr, 65 Torr to 100 Torr, 70 Torr to 100 Torr, 75 Torr to 100 Torr, 80 Torr to 100 Torr, 85 Torr to 100 Torr, 90 Torr to 100 Torr, 95 Torr to 100 Torr, 1 Torr to 95 Torr, 1 Torr to 90 Torr, 1 Torr to 85 Torr, 1 Torr to 80 Torr, 1 Torr to 75 Torr, or 1 Torr to 70 Torr. In other further embodiments, the deposition pressure may be a pressure of 1 m Torr to 100 m Torr, 1 mTorr to 90 mTorr, 1 mTorr to 80 mTorr, 1 mTorr to 70 m Torr, 1 m Torr to 60 m Torr, 1 m Torr to 50 m Torr, 1 m Torr to 40 mTorr, 1 mTorr to 30 m Torr, 1 m Torr to 20 m Torr, 1 mTorr to 10 mTorr, 100 m Torr to 300 m Torr, 150 m Torr to 300 m Torr, 200 m Torr to 300 m Torr, or 150 m Torr to 250 m Torr, or 150 mTorr to 225 m Torr.

The substrate may comprise at least one of Si, Co, Cu, Al, W, WN, WC, TIN, Mo, MOC, SiO₂, W, SiN, WCN, Al₂O₃, AlN, ZrO₂, La₂O₃, TaN, RuO₂, IrO₂, Nb₂O₃, Y₂O₃, hafnium oxide, or any combination thereof.

In some embodiments, the silicon-containing film comprises at least one of at least one of silicon, silicon nitride, silicon oxynitride, silicon oxide, silicon dioxide, silicon carbide, silicon carbonitride, silicon oxycarbonitride, carbon-doped silicon nitride, carbon-doped silicon oxide, carbon-doped silicon oxynitride, or any combination thereof. In some embodiments, the substrate may comprise other silicon-based substrates, such as, for example, one or more of polysilicon substrates, metallic substrates, and dielectric substrates.

Some embodiments relate to an article. In some embodiments, the article comprises a semiconductor device. In some embodiments, the article comprises a microelectronic device. In some embodiments, the article comprises a component of a semiconductor device. In some embodiments, the article comprises a component of a microelectronic device. In some embodiments, the article comprises a substrate. In some embodiments, the article comprises a film located on the substrate. In some embodiments, the film comprises a reaction product of a precursor and a co-reactant, optionally in a presence of a catalyst (e.g., an aluminum catalyst). It will be appreciated that the film can be formed according to any one or more of the methods disclosed herein, without departing from the scope of this disclosure. It will also be appreciated that the precursor can comprise any one or more of the precursors disclosed herein, without departing from the scope of this disclosure.

Any one or more of the embodiments disclosed herein shall be understood to be combinable without departing from the scope or spirit of the disclosure.

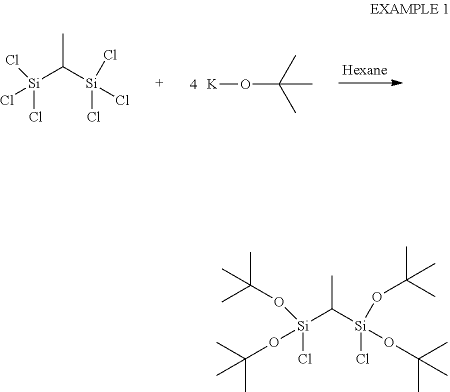

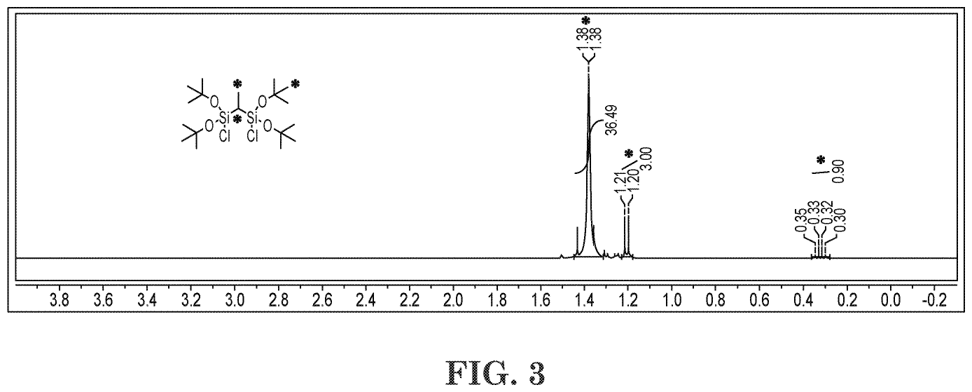

To a n-Hexane suspension (500 ml) of potassium tert-butoxide (52.9 g, 0.47 mol), a n-Hexane (25 ml) solution of bis(trichlorosilyl) ethane (35 g, 0.12 mol) was slowly added at −10° C. The reaction temperature was gradually increased to room temperature, and then heated under reflux for 12 h. After cooling to room temperature, the mixture was filtered through Celite on a glass filter. The volatiles were then removed under reduced pressure at room temperature and Precursor A was purified by vacuum distillation (100° C. at 2.6 Torr) as a colorless liquid. Yield 40 g (74.5%). See 1H NMR spectra for Product A (FIG. 3).

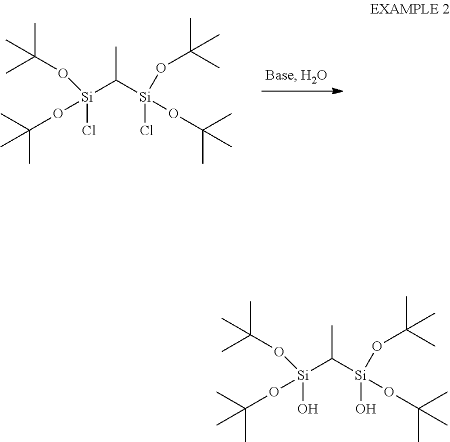 [SMILES: CC([Si](Cl)(OC(C)(C)C)OC(C)(C)C)[Si](Cl)(OC(C)(C)C)OC(C)(C)C ; CC([Si](O)(OC(C)(C)C)OC(C)(C)C)[Si](O)(OC(C)(C)C)OC(C)(C)C]

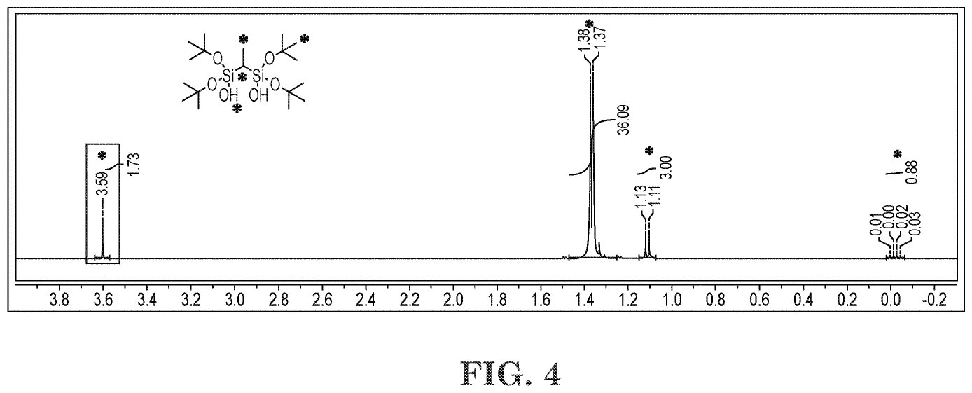

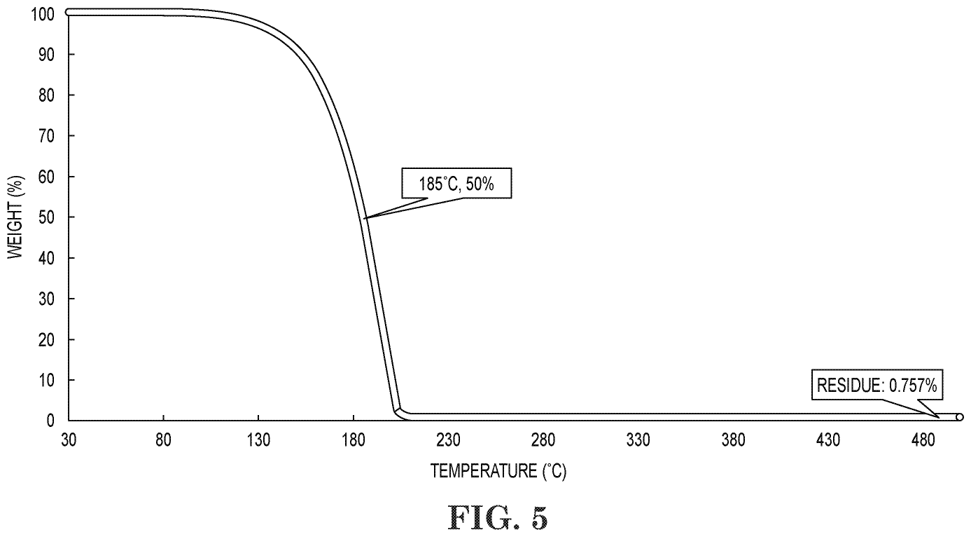

To Precursor A (20 g, 0.05 mol) and 38 ml of triethylamine (excess, 0.27 mol), 25 ml of H₂O (excess, 1.34 mol) at 0° C. was slowly added. The reaction mixture was stirred for 4 hours at room temperature, and then extracted with diethyl ether (2×50 ml). The layers were separated, and the organic layer was dried over MgSO₄. The solution was filtered, and solvent was removed under reduced pressure at room temperature, and Product B was purified by vacuum distillation (100° C., 4 Torr) as a colorless oil. Yield 13 g (70.3%). See 1H NMR spectra for Product B (FIG. 4) and TGA analysis for Product B (FIG. 5).

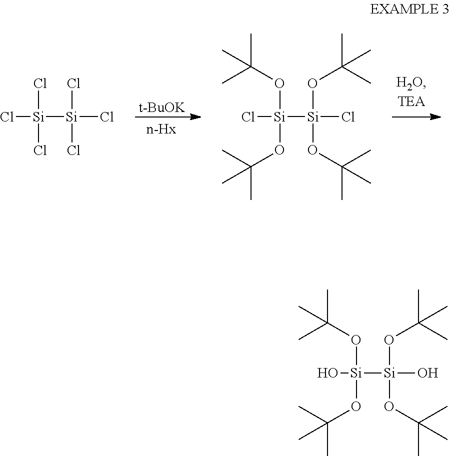 [SMILES: "t-BuOK" ; Cl[Si](Cl)(Cl)[Si](Cl)(Cl)Cl ; CC(C)(C)O[Si](Cl)(OC(C)(C)C)[Si](Cl)(OC(C)(C)C)OC(C)(C)C ; CC(C)(C)O[Si](O)(OC(C)(C)C)[Si](O)(OC(C)(C)C)OC(C)(C)C]

### Step 1) 1,1,2,2-Tetra-tert-butoxy-1,2-dichlorodisilane Synthesis

To a vessel containing a mixture of potassium tert-butoxide (t-BuOK, 66.8 g, 0.595 mol) and n-hexane (n-Hx, 500 g), hexachlorodisilane (HCDS, 40 g, 0.149 mol) was added at −20° C. slowly dropwise for 30 minute under nitrogen atmosphere. The reaction was stirred at room temperature for 20 h. And then, the reaction mixture was filtered through a celite cake with n-hexane. The filtrate was concentrated at 50° C. and 100 torr. The crude [intermediate] products were used as starting materials for the next step without further purification. Crude product is off-white solid (35 g, 45% yield)

### Step 2) 1,1,2,2-Tetra-tert-butoxy-1,2-disilanediol Synthesis

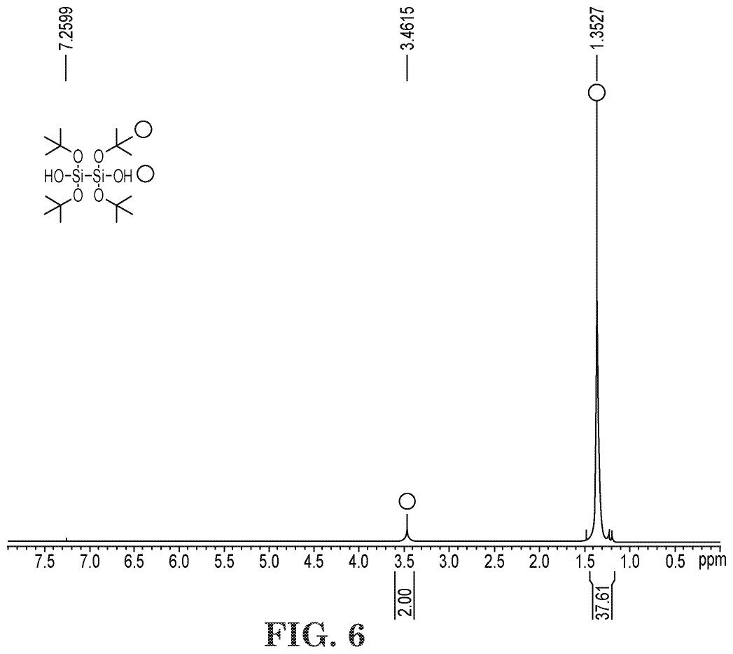

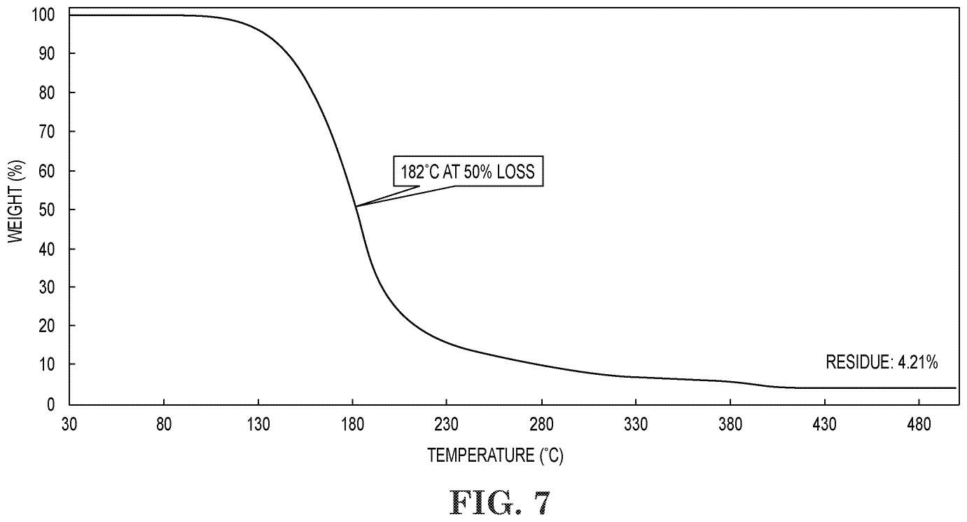

To a vessel containing 1,1,2,2-tetra-tert-butoxy-1,2-dichlorodisilane (TTBODS, 35 g, 0.083 mol), triethylamine (TEA, 34 g, 0.334 mol) and water (H₂O, 60 g, 3.34 mol) were slowly added in order at 0° C. The reaction was stirred at room temperature for 5 h. Upon completion of the reaction, the product was extracted with Et₂O and dried over MgSO₄. The organic phase was concentrated at 50° C. and 100 torr. The product was purified by sublimation to yield the final product as an off-white solid (11 g, 34.5% yield). See 1H NMR spectra for final product (FIG. 6) and TGA analysis for final product (FIG. 7).

### ASPECTS

Various Aspects are described below. It is to be understood that any one or more of the features recited in the following Aspect(s) can be combined with any one or more other Aspect(s).
Aspect 1. A composition comprising:
   a precursor,
      wherein the precursor comprises a compound of the formula:

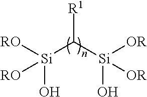

where:
R is independently a hydrogen or an alkyl, or two of the R attached to the Si are bonded to form a heterocyclic ring;
R¹ is independently at least one of an alkyl, an alkenyl, an alkoxy, an aryl, a cycloalkyl, or any combination thereof; and
n is 0 to 3;
wherein, when at least the precursor is exposed to a substrate, and optionally a catalyst, under deposition conditions, the precursor forms a film having less than 1% by weight of an impurity based on a total weight of the film.
Aspect 2. The composition according to Aspect 1, wherein n is 0 and R is a linear alkyl.
Aspect 3. The composition according to any one of Aspects 1-2, wherein n is 0 and R is a branched alkyl.
Aspect 4. The composition according to any one of Aspects 1-3, wherein n is 0 and R is a C₁-C₅ alkyl.
Aspect 5. The composition according to any one of Aspects 1-4, wherein n is 1 and R is a linear alkyl.
Aspect 6. The composition according to any one of Aspects 1-5, wherein n is 1 and R is a branched alkyl.
Aspect 7. The composition according to any one of Aspects 1-6, wherein n is 1 and R is a C₁-C₅ alkyl.
Aspect 8. The composition according to any one of Aspects 1-7, wherein two of the R attached to the Si are bonded to form a C₃-C₁₀ heterocyclic ring.
Aspect 9. The composition according to any one of Aspects 1-8, wherein the precursor is present in the composition at a purity of at least 99% as determined by 1H NMR.
Aspect 10. The composition according to any one of Aspects 1-9, wherein the precursor comprises at least one of:

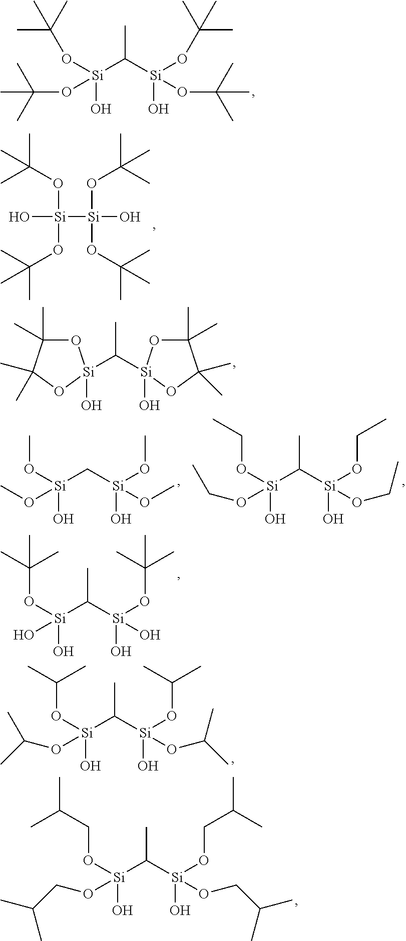

or any combination thereof.
Aspect 11. A method comprising:
   exposing, under deposition conditions, a substrate to at least a precursor of the formula:

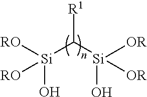

where:
   R is independently a hydrogen or an alkyl, or two of the R attached to the Si are bonded to form a heterocyclic ring;
   R¹ is independently at least one of an alkyl, an alkenyl, an alkoxy, an aryl, a cycloalkyl, or any combination thereof; and
   n is 0 to 3.
Aspect 12. The method according to Aspect 11, further comprising:
   obtaining a substrate comprising an aluminum catalyst located on the substrate.
Aspect 13. The method according to Aspect 12, wherein the step of obtaining the substrate comprises:
   depositing an aluminum film on the substrate; and
   heating the aluminum film to at least an Al—Si eutectic temperature.
Aspect 14. The method according to any one of Aspects 11-13, wherein the step of exposing comprises:
   vaporizing the precursor to obtain a precursor vapor; and
   flowing the precursor vapor to a chamber containing the substrate.
Aspect 15. The method according to any one of Aspects 11-14, further comprising:
   exposing, under deposition conditions, the substrate to a co-reactant.
Aspect 16. The method according to any one of Aspects 11-15, wherein n is 0 and R is a linear alkyl.
Aspect 17. The method according to any one of Aspects 11-16, wherein n is 0 and R is a branched alkyl.
Aspect 18. The method according to any one of Aspects 11-17, wherein n is 1 and R is a linear alkyl.
Aspect 19. The method according to any one of Aspects 11-18, wherein n is 1 and R is a branched alkyl.
Aspect 20. The method according to any one of Aspects 11-19, wherein n is 0 or 1 and R is a C₁-C₅ alkyl.
Aspect 21. The method according to any one of Aspects 11-20, wherein two of the R attached to the Si are bonded to form a C₃-C₁₀ heterocyclic ring.
Aspect 22. The method according to any one of Aspects 11-21, wherein the precursor comprises at least one of:

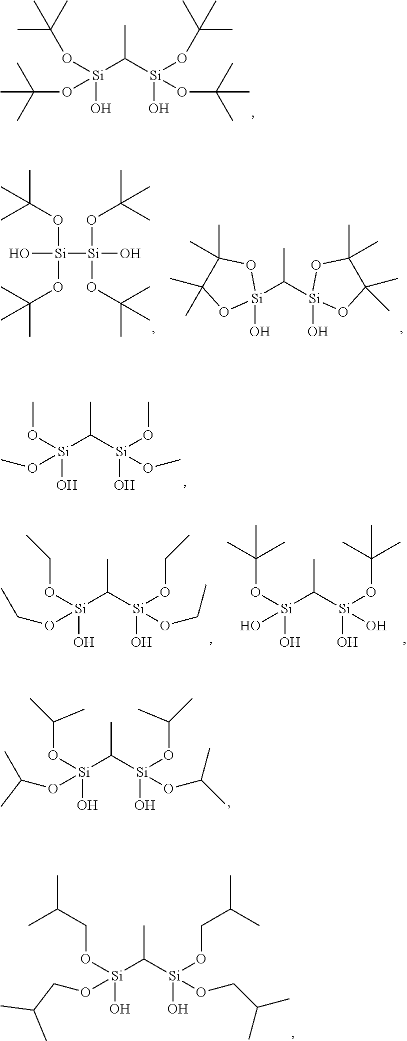

or any combination thereof.
Aspect 23. A method comprising:
   combining, under first reaction conditions, a reagent compound, with a metal alkoxide compound or a hydroxyl-containing compound, and a solvent, to obtain a first reaction product;
      wherein the reagent compound comprises a compound of the formula:

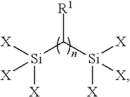

where:
X is independently a halide;
R¹ is independently at least one of an alkyl, an alkenyl, an alkoxy, an aryl, a cycloalkyl, or any combination thereof; and
n is 0 to 3;
wherein the first reaction product comprises a compound of the formula:

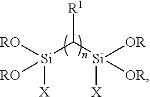

where:
X is independently a halide;
R is independently a hydrogen or an alkyl, or two of the R attached to the Si are bonded to form a heterocyclic ring;
R¹ is independently at least one of an alkyl, an alkenyl, an alkoxy, an aryl, a cycloalkyl, or any combination thereof; and
n is 0 to 3;
combining, under second reaction conditions, a base compound with the first reaction product to form a precursor,
   wherein the precursor comprises a compound of the formula:

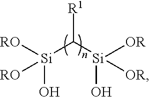

where:
R is independently a hydrogen or an alkyl, or two of the R attached to the Si are bonded to form a heterocyclic ring;
R¹ is independently at least one of an alkyl, an alkenyl, an alkoxy, an aryl, a cycloalkyl, or any combination thereof; and
n is 0 to 3.
Aspect 24. The method according to Aspect 23, wherein n is 0 and R is a linear alkyl. Aspect 25. The method according to any one of Aspects 23-24, wherein n is 0 and R is a branched alkyl.
Aspect 26. The method according to any one of Aspects 23-25, wherein n is 0 and R is a C₁-C₅ alkyl.
Aspect 27. The method according to any one of Aspects 23-26, wherein n is 1 and R is a linear alkyl.
Aspect 28. The method according to any one of Aspects 23-27, wherein n is 1 and R is a branched alkyl.
Aspect 29. The method according to any one of Aspects 23-28, wherein n is 1 and R is a C₁-C₅ alkyl.
Aspect 30. The method according to any one of Aspects 23-29, wherein two of the R attached to the Si are bonded to form a C₃-C₁₀ heterocyclic ring.
Aspect 31. The method according to any one of Aspects 23-30, wherein the precursor comprises at least one of:

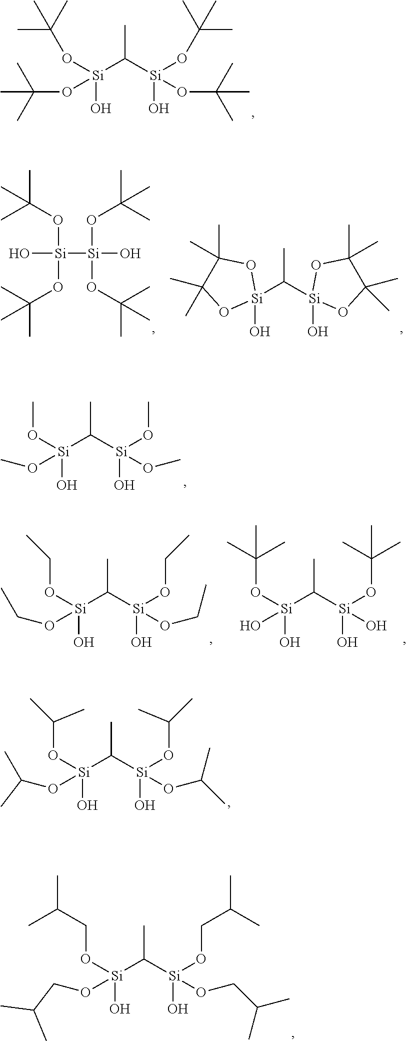

or any combination thereof.
Aspect 32. An article comprising:
   a substrate; and
   a film located on the substrate,
      wherein the film comprises a reaction product of a precursor and a co-reactant, optionally in a presence of a catalyst,
         wherein the precursor comprises a compound of the formula:

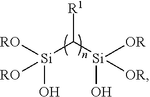

where:
R is independently a hydrogen or an alkyl, or two of the R attached to the Si are bonded to form a heterocyclic ring;
R¹ is independently at least one of an alkyl, an alkenyl, an alkoxy, an aryl, a cycloalkyl, or any combination thereof; and
n is 0 to 3.

What is claimed is:

1. A composition comprising:
a precursor,
wherein the precursor comprises a compound of the formula: 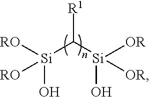
where:
R is independently a hydrogen or an alkyl, or two of the R attached to the Si are bonded to form a heterocyclic ring;
R¹ is independently at least one of an alkyl, an alkenyl, an alkoxy, an aryl, a cycloalkyl, or any combination thereof; and
n is 0 to 3;
wherein, when at least the precursor is exposed to a substrate under deposition conditions, the precursor forms a film having less than 1% by weight of an impurity based on a total weight of the film.

2. The composition of claim 1, wherein n is 0 and R is a linear alkyl.

3. The composition of claim 1, wherein n is 0 and R is a branched alkyl.

4. The composition of claim 1, wherein n is 0 and R is a C₁-C₅ alkyl.

5. The composition of claim 1, wherein n is 1 and R is a linear alkyl.

6. The composition of claim 1, wherein n is 1 and R is a branched alkyl.

7. The composition of claim 1, wherein n is 1 and R is a C₁-C₅ alkyl.

8. The composition of claim 1, wherein two of the R attached to the Si are bonded to form a C₃-C₁₀ heterocyclic ring.

9. The composition of claim 1, wherein the precursor is present in the composition at a purity of at least 99% as determined by 1H NMR.

10. The composition of claim 1, wherein the precursor comprises at least one of: 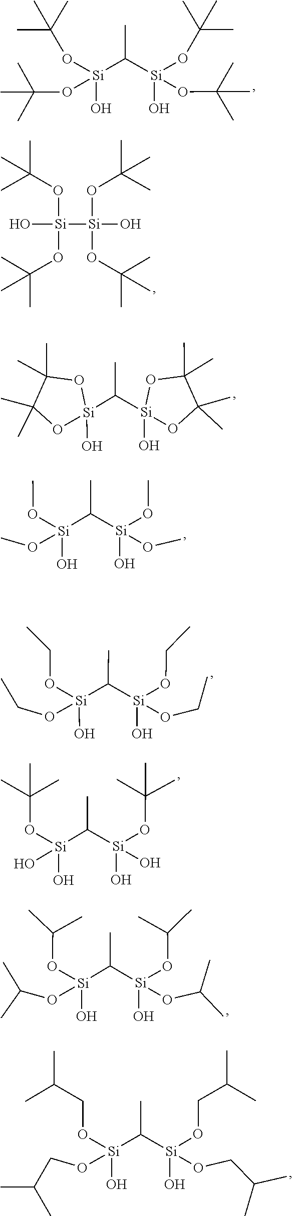
or any combination thereof.

11. A method comprising:
exposing, under deposition conditions, a substrate to at least a precursor of the formula: 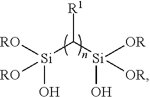
where:
R is independently a hydrogen or an alkyl, or two of the R attached to the Si are bonded to form a heterocyclic ring;
R¹ is independently at least one of an alkyl, an alkenyl, an alkoxy, an aryl, a cycloalkyl, or any combination thereof; and
n is 0 to 3.

12. The method of claim 11, further comprising:
obtaining a substrate comprising an aluminum catalyst located on the substrate.

13. The method of claim 12, wherein the step of obtaining the substrate comprises:
depositing an aluminum film on the substrate; and
heating the aluminum film to at least an Al—Si eutectic temperature.

14. The method of claim 11, wherein the step of exposing comprises:
vaporizing the precursor to obtain a precursor vapor; and
flowing the precursor vapor to a chamber containing the substrate.

15. The method of claim 11, further comprising:
exposing, under deposition conditions, the substrate to at least a co-reactant.

16. A method comprising:
combining, under first reaction conditions, a reagent compound, with a metal alkoxide compound or a hydroxyl-containing compound, and a solvent, to obtain a first reaction product;
wherein the reagent compound comprises a compound of the formula: 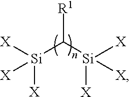
where:
X is independently a halide;
R¹ is independently at least one of an alkyl, an alkenyl, an alkoxy, an aryl, a cycloalkyl, or any combination thereof; and
n is 0 to 3;
wherein the first reaction product comprises a compound of the formula: 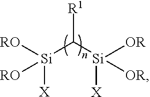
where:
X is independently a halide;
R is independently a hydrogen or an alkyl, or two of the R attached to the Si are bonded to form a heterocyclic ring;
R¹ is independently at least one of an alkyl, an alkenyl, an alkoxy, an aryl, a cycloalkyl, or any combination thereof; and
n is 0 to 3; and
combining, under second reaction conditions, a base compound with the first reaction product to form a precursor,
wherein the precursor comprises a compound of the formula: 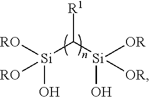
where:
R is independently a hydrogen or an alkyl, or two of the R attached to the Si are bonded to form a heterocyclic ring;
R¹ is independently at least one of an alkyl, an alkenyl, an alkoxy, an aryl, a cycloalkyl, or any combination thereof; and
n is 0 to 3.

17. The method of claim 16, wherein n is 0 and R is a linear alkyl.

18. The method of claim 16, wherein n is 0 and R is a branched alkyl.

19. The method of claim 16, wherein two of the R attached to the Si are bonded to form a C₃-C₁₀ heterocyclic ring.

20. The method of claim 16, wherein the precursor comprises at least one of: 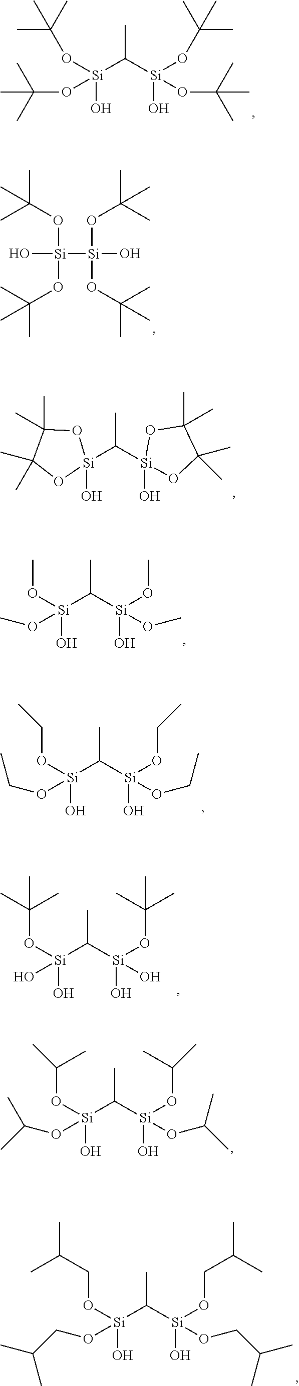
or any combination thereof.
